(19) United States
(12) Patent Application Publication
(10) Pub. No.: US 2011/0001905 A1
(43) Pub. Date: Jan. 6, 2011

(54) TRANSPARENT THIN-FILM ELECTRODE

(75) Inventor: Toshihiko Tanaka, Inashiki-gun (JP)

Correspondence Address: SUGHRUE MION, PLLC, 2100 PENNSYLVANIA AVENUE, N.W., SUITE 800, WASHINGTON, DC, 20037, US

(73) Assignee: SUMITOMO CHEMICAL COMPANY, LIMITED, Chuo-ku, Tokyo (JP)

(21) Appl. No.: 12/919,143

(22) PCT Filed: Feb. 25, 2009
(86) PCT No.: PCT/JP2009/053317

§ 371 Date: Aug. 24, 2010

(30) Foreign Application Priority Data
Feb. 28, 2008 (JP) 2008-047539

(51) Int. Cl. G02F 1/1335; H01L 51/52; H01J 1/02; G02B 27/28; G02F 1/1343; B05D 5/12

(52) U.S. Cl. 349/96; 313/504; 313/112; 359/485; 349/139; 427/77; 977/952

(57) ABSTRACT

Provided is a transparent thin-film electrode characterized in that light transmitted through the transparent thin-film electrode is polarized. The transparent thin-film electrode comprises a conductive polymer or the transparent thin-film electrode comprises a carbon nanotube. Consequently, the transparent thin-film electrode and a liquid crystal display device or a light-emitting element using the same which has industrially satisfactory performance can be provided without using indium that has a problem in terms of stable supply and cost because the amount of indium as a resource is small and the price thereof rises sharply due to stringent demand.

### TECHNICAL FIELD

The present invention relates to a transparent thin-film electrode used in a liquid crystal display, a light-emitting device, and the like.

### BACKGROUND ART

In recent years, the uses of liquid crystal displays have expanded dramatically. And, in almost all liquid crystal displays, a transparent thin-film electrode containing indium tin oxide (which is generally called ITO) is used. The transparent thin-film electrode containing ITO has both high electrical conductivity and high transparency, and has become essential for the spread of the liquid crystal displays. Also, in various light-emitting diodes which have been actively studied in recent years, particularly in organic light-emitting diodes (which are generally called OLEDs or organic ELs) containing organic molecules as a light-emitting material, a transparent thin-film electrode which is an electrode for injecting electrical charges to the light-emitting material as well as through which light from the light-emitting material can be transmitted is essential for their spread, and therefore, transparent thin-film electrodes consisting of ITO and having no polarization property are widely used as in the case of the liquid crystal displays.

However, there are problems with the use of indium in terms of stable supply and cost because its price rises sharply due to its poor resource reserve and tightness in supply and demand, and so on. Therefore, many alternative materials, mainly inorganic oxides, have been studied. Among these studies, conductive polymers (for example, see PATENT DOCUMENT 1) and carbon nanotubes are considered to be ideal materials in that they do not substantially contain rare metal and there are no problems of resource supply and cost. However, there is still the problem that they have lower conductivity than ITO. When the thin-film electrode is thickened to resolve this problem, another problem that the transparency decreases and thus the thin-film electrode is not usable occurs.

### DISCLOSURE OF THE INVENTION

### Problems to be Solved by the Invention

It is an object of the present invention to provide a transparent thin-film electrode using no indium as a material. Also, it is an object of the present invention to provide a liquid crystal display or light-emitting device having industrially sufficient performance by using the transparent thin-film electrode.

### Means for Solving the Problems

Accordingly, the present inventors have diligently studied transparent thin-film electrodes over and over. As the result, the present inventors have surprisingly found the facts that in the cases where conductive polymers, carbon nanotubes, anisotrapic metal fine particles, or metal wires used in a transparent thin-film electrode are oriented, and further a liquid crystal display or light-emitting device is formed considering the polarization direction of the transparent thin-film electrode which occurs there, a thin film providing the polarization of transmitted light can be sufficiently used as a transparent thin-film electrode. And thus, the present invention has been completed.

Specifically, the present invention provides the following [1] to [25].

[1] A transparent thin-film electrode, wherein light transmitted through the transparent thin-film electrode is polarized.
[2] The transparent thin-film electrode according to the above [1] comprising a conductive polymer.
[3] The transparent thin-film electrode according to the above [1] comprising a carbon nanotube.
[4] The transparent thin-film electrode according to the above [1] comprising an anisotropic metal fine particle.
[5] The transparent thin-film electrode according to the above [1] comprising a wire grid structure of metal.
[6] The transparent thin-film electrode according to the above [5] comprising a film comprising a conductive polymer or a carbon nanotube.
[7] The transparent thin-film electrode according to the above [6], wherein the film comprising a conductive polymer or a carbon nanotube is disposed in a gap between adjacent metal wires forming the wire grid structure of metal.
[8] The transparent thin-film electrode according to [6] or [7], wherein the film comprising a conductive polymer or a carbon nanotube is laminated on the wire grid structure of metal.
[9] A composite transparent thin-film electrode comprising the transparent thin-film electrode according to [5] and the transparent thin-film electrode according to any one of [2] to [4].
[10] The transparent thin-film electrode according to [9], wherein the transparent thin-film electrode according to any one of [2] to [4] is laminated on the wire grid structure of metal.
[11] The transparent thin-film electrode according to [9], wherein the transparent thin-film electrode according to any one of [2] to [4] is disposed in a gap between metal wires forming the wire grid structure of metal.
[12] The transparent thin-film electrode according to any one of [9] to [11], wherein the polarization direction of the wire grid structure of metal substantially matches the polarization direction of the transparent thin-film electrode according to any one of [2] to [4].
[13] The transparent thin-film electrode according to any one of the above [1] to [12], wherein an orientation degree S in the transparent thin-film electrode is 0.1 or more.
[14] The transparent thin-film electrode according to any one of the above [1] to [13], wherein in a transmitted polarized absorption spectrum of light having a wavelength of 300 to 700 nm of the transparent thin-film electrode, a maximum absorbance value A1 of a polarized light in all directions in a film plane of a thin film is 0.1 or more.
[15] An electrode composite comprising the transparent thin-film electrode according to any one of the above [1] to [14] and at least one auxiliary electrode in contact with the transparent thin-film electrode.
[16] The electrode composite according to the above [15], wherein a maximum value Lmax of the length L of a path from a point X on a surface of the transparent thin-film electrode not in contact with the auxiliary electrode to the auxiliary electrode, the path being perpendicular to a polarization direction of light transmitted through the transparent thin-film electrode and being shortest, is smaller than half a square root of a surface area J of the transparent thin-film electrode not in contact with the auxiliary electrode.
[17] The electrode composite according to the above [15] or [16], wherein a maximum value Lmax of the length L of a path from a point X on the surface of the transparent thin-film electrode not in contact with the auxiliary electrode to the auxiliary electrode, the path being perpendicular to the polarization direction of light transmitted through the transparent thin-film electrode and being shortest, is smaller than 5 cm.
[18] A liquid crystal display comprising the transparent thin-film electrode according to any one of the above [1] to [14] or the electrode composite according to any one of the above [15] to [17].
[19] The liquid crystal display according to the above [18], further comprising at least one polarizing device, wherein the polarization direction of at least one polarizing device substantially matches the polarization direction of the transparent thin-film electrode.
[20] A light-emitting device comprising the transparent thin-film electrode according to any one of the above [1] to [14] or the electrode composite according to any one of the above [15] to [17], and further a light-emitting layer, wherein light emitted from the light-emitting layer is polarized, and the polarization direction of the light-emitting layer substantially matches the polarization direction of the transparent thin-film electrode.
[21] The light-emitting device according to the above [20], wherein the light-emitting device is a light-emitting diode.
[22] The light-emitting device according to the above [21], wherein a light-emitting layer of the light-emitting diode comprises an oriented organic molecule.
[23] The light-emitting device according to the above [22], wherein the organic molecule is a polymer.
[24] The light-emitting device according to any one of the above [20] to [23] comprising at least one orientation-inducing layer between the light-emitting layer and the transparent thin-film electrode.
[25] A method for manufacturing the transparent thin-film electrode according to the above [1] or [2], the method comprising applying a force to a film comprising a solvent and a conductive polymer.

### ADVANTAGES OF THE INVENTION

The transparent thin-film electrode of the present invention can be preferably used in a liquid crystal display, light-emitting device, and the like at a low cost without using indium of rare metal resources. Also, the conductivity in a particular direction in a plane is high, and the transmittance of light polarized in a particular direction in a plane is high. Therefore, in the liquid crystal display and light-emitting device of the present invention, the transparent thin-film electrode of the present invention can be used as a transparent thin-film electrode without decreasing light use efficiency. Also, in the electrode composite of the present invention obtained by suitable combination with an auxiliary electrode, the effects thereof can be more significantly increased.

### BRIEF DESCRIPTION OF THE DRAWINGS

FIG. 1 shows the structure of an electrode composite in Example 1;

FIG. 2 shows the structure of a liquid crystal display device in Example 2;

FIG. 3 shows the structure of a light-emitting device in Example 3; and

FIG. 4 shows the structure of a transparent thin-film electrode in Example 8.

### DESCRIPTION OF REFERENCE NUMERALS

1 transparent thin-film electrode
2 a portion where the transparent thin-film electrode is in contact with an auxiliary electrode
3 the polarization direction of light which is transmitted through the transparent thin-film electrode 1
4 a point X on the surface of the transparent thin-film electrode not in contact with the auxiliary electrode
5 the shortest length L of a path from a point X on the surface of the transparent thin-film electrode not in contact with the auxiliary electrode to the auxiliary electrode, the path being perpendicular to the polarization direction of light transmitted through the above transparent thin-film electrode
6 transparent thin-film electrode (cross section)
6′ transparent thin-film electrode (cross section)
7 auxiliary electrode (cross section)
8 substrate (cross section)
9 polarizing film (transmitted light is polarized in the direction 13)
10 liquid crystal orientation-inducing layer (the director of a liquid crystal on a surface is oriented in the direction 13)
11 TN-oriented liquid crystal
12 liquid crystal orientation-inducing layer (the director of a liquid crystal on a surface is oriented in the direction 14)
13 the polarization direction of light transmitted through the transparent thin-film electrode 6
14 the polarization direction of light transmitted through the transparent thin-film electrode 6′
15 polarizing film (transmitted light is polarized in the direction 14)
16 substrate
17 substrate
18 hole transport layer
19 light-emitting layer (light emission is polarized in the direction 21)
20 cathode
21 the polarization direction of light transmitted through the transparent thin-film electrode 1
22 transparent thin-film electrode
23 substrate
24 layer of a conductive polymer
25 metal electrode

### BEST MODE FOR CARRYING OUT THE INVENTION

The present invention will be described in detail below.

The transparent thin-film electrode of the present invention is characterized in that light (which is usually unpolarized light) which is transmitted through the transparent thin-film electrode is polarized. Here, this polarization means polarization when light enters perpendicularly to a film surface and is transmitted. Also, in the present invention, the polarization direction of the transparent thin-film electrode means the vibration direction of the electric field in transmitted light under such entrance conditions. The material of such a transparent thin-film electrode in which the transmitted light is polarized can be appropriately selected from materials known to have electrical conductivity and property of polarizing the transmitted light, and can be used. Conductive polymers, carbon nanotubes, anisotropic metal fine particles, such as metal nanorods, metal wires, and the like are known as such materials. In terms of electrical conductivity and polarization, conductive polymers, carbon nanotubes, and metal wires are preferred. As for the metal wires, a wire grid structure of metal called a wire grid polarizer is used.

The transparent thin-film electrode of the present invention may comprise other materials (accessory components) without imparing its function in addition to the above materials known to have electrical conductivity and property of polarizing the transmitted light. Examples of such accessory components include a dopant, a binder, a plasticizer, a stabilizer, and a liquid crystal-orienting agent. In general, the content of such accessory components except for a dopant among these is preferably low to decrease the resistance of the transparent thin-film electrode. Specifically, the weight fraction of such accessory components is preferably 50% or less, further preferably 30% or less, still more preferably 20% or less, and particularly preferably 10% or less. On the other hand, as for the dopant, the optimum dopant content of the conductive polymer used can be appropriately selected and determined according to the combination of the conductive polymer used and the dopant. Specifically, the optimum dopant content is determined considering stability, light absorption, conductivity, the mass of the dopant, and the like. Usually, the weight fraction of the dopant is preferably 1% or more and 98% or less, more preferably 3% or more and 90% or less, further preferably 5% or more and 85% or less, still more preferably 5% or more and 50% or less, and particularly preferably 5% or more and 30% or less. In the case of wire grid polarizers, these accessory components can be usually formed on the surfaces of the metal wires or in gaps between the metal wires constituting these.

The conductive polymers used in the present invention will be described. In general, the conductive polymers can be appropriately selected from polymers known as conductive polymers, and can be used. Examples of such polymers can include polyacetylene, polyparaphenylenevinylene, polypyrrole, polyaniline, polythiophene, and derivatives thereof. Among these, polypyrrole, polyaniline, polythiophene, and derivatives thereof are preferred in terms of stability in a doped state.

Although depending on the method for manufacturing the transparent thin-film electrode, a derivative or the like soluble in the solution can be used when the transparent thin-film electrode is manufactured through the solution of a conductive polymer. Examples of such a derivative can include derivatives obtained by introducing various alkyl chains or alkoxy chains into the side chain of the conductive polymer, and derivatives obtained by using organic acids, such as benzenesulfonic acid, camphorsulfonic acid, and polystyrene sulfonic acid, as the dopant of the conductive polymer. Specific examples thereof can include poly(3,4-ethylenedioxythiophene) doped with polystyrene sulfonic acid. Also, a polymer can be dissolved using no derivative, depending on the solvent. Examples thereof can include polyaniline dissolved in dimethylformamide or concentrated sulfuric acid. Also, when the intermediate of the conductive polymer has solubility, methods can also be used in which the intermediate is casted, applied, or subjected to build-up of LB films or the like, and converted to the conductive polymer by heat treatment or the like, and further the conductive polymer is doped. Specific examples thereof include polyparaphenylenevinylene obtained from a soluble polymeric sulfonium salt, and derivatives thereof.

Next, a method for manufacturing a transparent thin-film electrode comprising a conductive polymer will be described. The method can be appropriately selected from well-known methods for manufacturing a thin film of an oriented conductive polymer. Specific examples of methods for forming a thin film can include application, printing, friction, transfer, vapor deposition, build-up of LB films, and the like. In these cases, examples of orientation treatment can include mechanical methods (e.g. stretching, rolling, and rubbing), methods for applying a magnetic field or an electric field, and methods using the orientation action of a surface. As for specific example, a polymer film to which a polymeric sulfonium salt is applied can be heated and stretched to manufacture an oriented thin film of polyparaphenylenevinylene. In the methods of using the orientation action of a surface, more specifically, the orientation actions of a clean surface of glass, silicon oxide, or the like, a surface modified with a surface treatment agent, a surface of a material subjected to deformation processing such as stretching and rolling, a surface of a polymer thin film obtained on a substrate by friction transfer, a surface of a rubbed material, and the like can be used.

The transparent thin-film electrode is formed on some flat and smooth substrate. The substrate is not particularly limited, as long as it is stable without preventing its purpose. For the purpose of the transparent thin-film electrode, the use of a transparent material is often required. Examples of such a transparent substrate can include substrates made of quartz, glass, transparent resin, and the like. In the case of using a light-emitting device, a device which has already formed partway is used as a substrate, and the transparent thin-film electrode can be further formed thereon. One of methods for manufacturing the transparent thin-film electrode of the present invention is a method for applying a solution of a doped conductive polymer and performing orientation. Also, one of the methods for manufacturing the transparent thin-film electrode of the present invention is a method for applying a solution of an undoped conductive polymer, performing orientation, and further performing doping. One of other preferred manufacturing methods includes a method for building up Langmuir-Blodgett films of an undoped or doped conductive polymer.

When the conductive polymer is soluble in a solvent, or when the conductive polymer is swelled in a solvent, the orientation method of the present invention can also be used. In other words, an orientation method for applying a force to a film comprising a solvent and a conductive polymer can also be used. In this case, the transparent thin-film electrode can be manufactured by applying a force to the film comprising a solvent and a conductive polymer in one direction and then removing the solvent. Examples of the method for applying a force can include stretching, friction, and compression. In this case, a doped conductive polymer is preferably used. Specific examples of the doped conductive polymer can include poly(3,4-ethylenedioxythiophene) doped with an organic acid, for example, polystyrene sulfonic acid.

In the transparent thin-film electrode of the present invention, the conductive polymer constituting the transparent thin-film electrode is preferably subjected to oxidation or reduction, that is to say, doped, in terms of the electrical conductivity of the transparent thin-film electrode. Next, the doping will be described. As the doping method, well-known doping methods can be used. Specific examples of the doping methods can include electrochemical doping and chemical doping. As the dopant, a well-known dopant can be appropriately selected. Examples of the dopant can include iodine, bromine, chlorine, oxygen, arsenic pentafluoride, various anions (various sulfonic acids, chlorine ions, nitric acid ions, and the like), sodium, potassium, and various cations (sodium ions and the like). Also, the doping can be performed before the thin film is formed, while the thin film is formed, and after the thin film is formed, according to the method for manufacturing the transparent thin-film electrode.

The carbon nanotubes used in the present invention will be described. As the carbon nanotubes, well-known carbon nanotubes can be used. Usually, carbon nanotubes having high purity are preferred. Also, while the presence of a semiconducting component and a metallic component in the carbon nanotube itself is well known, it is preferable that the ratio of the metallic component is high in terms of electrical conductivity. In the present invention, a thin film in which such carbon nanotubes are oriented is formed. Examples of the orientation method can include mechanical methods (stretching, rolling, rubbing, and the like), methods for applying a magnetic or electric field, and methods of using the orientation action of a surface. Specific examples thereof include a method for forming a monomolecular film on a water surface and building up an LB film.

The wire grid structure used in the present invention will be described. Specifically, as the metal wire grid polarizer, well-known metal wire grid polarizers can be used. The type of the metal is not particularly limited as long as it is stable and it can be processed into the shape of a wire on a flat and smooth substrate. A simple substance or alloy can be used. Examples of the metal can include gold, silver, aluminum, chromium, and copper, and alloys thereof. In order to increase adhesion to the substrate, it is also possible to previously perform adhering another material thinly to a substrate surface and then adhering the above metal, if needed. As the method for manufacturing the wire grid structure, well-known methods for manufacturing a wire grid polarizer for visible light can be used. For example, a method for obtaining the fine lines and spaces of a metal film by the use of a resist pattern of submicron fine lines and spaces obtained by interference exposure or electron beam lithography is widely known. Also, a method for forming a metal film on a transparent flexible substrate and stretching the substrate and the metal film is known.

The wire grid structure used in the present invention can also be combined with conductive polymers or carbon nanotubes to provide the transparent thin-film electrode of the present invention. In this case, it is preferable that a film comprising a conductive polymer or carbon nanotubes is formed in gaps between metal wires forming the wire grid structure, or laminated on the entire wire grid structure to be formed.

The wire grid structure used in the present invention can also be further combined with another type of second transparent thin-film electrode of the present invention to provide one composite transparent thin-film electrode. A transparent thin-film electrode comprising a conductive polymer, carbon nanotubes, or anisotropic metal fine particles can be used as such another type of transparent thin-film electrode of the present invention. In this case, it is preferable that the second transparent thin-film electrode is formed in gaps between metal wires forming the wire grid structure, or laminated on the wire grid structure to be formed. Also, in this case, it is preferable that a polarization direction specific to the wire grid structure substantially matches a polarization direction specific to the second transparent thin-film electrode. Here, a specific polarization direction means the polarization direction of light which is transmitted perpendicularly through each transparent thin-film electrode in the case where each transparent thin-film electrode of the above wire grid structure or the above film exists alone.

Generally, the orientation degree (orientation order parameter) S of the transparent thin-film electrode of the present invention is preferably high. Here, the orientation degree substantially means an index obtained by evaluating the polarization of light which is transmitted through each transparent thin-film electrode. For example, when the transparent thin-film electrode is of the conductive polymer, the orientation degree is usually known as an index correlated to the orientation state of the molecules. Also, in the cases of the carbon nanotubes, anisotropic metal fine particles, and metal wires, the orientation degree is similarly an index correlated to some orientation state. Specifically, S is preferably 0.1 or more, more preferably 0.2 or more, further preferably 0.5 or more, still further preferably 0.6 or more, and particularly preferably 0.7 or more. S can be measured by well-known methods, such as a polarized absorption spectrum and X-ray diffraction. Usually, it is possible to use S defined by a method for measuring a polarized spectrum of transmitted light, obtaining a dichroic ratio D=A1/A2 from absorbance A1 for the incident light polarized in a direction in which the absorbance of the polarized spectrum of transmitted light is maximum, and absorbance A2 for the incident light polarized in a direction orthogonal to the direction, and calculating S=(D−1)/(D+2). Here, the incident light is allowed to enter perpendicularly to a flat surface of the transparent thin-film electrode. Also, as for the measured wavelength, a wavelength at which A1 is maximum is generally used. However, when the maximum is not clear, a wavelength at which A1 is comparatively large, in the wavelength region of the visible region, can be appropriately selected and used. Also, in the present invention, a polarization direction represents a direction in which the projection of the electric field vector of light is maximum in a plane perpendicular to the travel direction of light.

In terms of polarization, S is preferably large. More specifically, S is preferably 0.1 or more, more preferably 0.3 or more, further preferably 0.5 or more, still more preferably 0.7 or more, and particularly preferably 0.8 or more. However, the transparent thin-film electrode with small A2 can be used as a transparent thin-film electrode having high transparency. Specifically, A2 is preferably 0.5 or less, further preferably 0.3 or less, still more preferably 0.1 or less, and particularly preferably 0.05 or less. Also, the case where S is 0.5 or more and A2 is 0.3 or less is preferred. The case where S is 0.7 or more and A2 is 0.3 or less is more preferred. The case where S is 0.8 or more and A2 is 0.2 or less is particularly preferred.

Next, the electrode composite of the present invention will be described. The electrode composite of the present invention comprises the transparent thin-film electrode and at least one auxiliary electrode in contact with the transparent thin-film electrode. When the transparent thin-film electrode is formed on a flat and smooth substrate, it is usually preferable that the auxiliary electrode is laminated on a portion in a plane of the transparent thin-film electrode, or the auxiliary electrode is formed in contact with the transparent thin-film electrode.

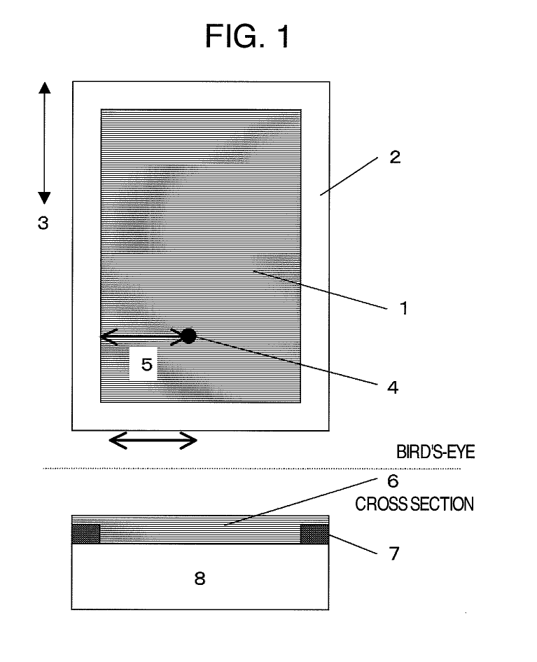

The disposition of the auxiliary electrode will be described. In terms of decreasing electrical resistance, a path from any point X on the surface of the transparent thin-film electrode not in contact with the auxiliary electrode to the auxiliary electrode is perpendicular to the polarization direction of light transmitted through the transparent thin-film electrode, and the maximum value Lmax of the shortest length L of the path is preferably smaller than half the square root of the surface area J of the transparent thin-film electrode not in contact with the auxiliary electrode, more preferably 45% or less of the square root of J, further preferably 40% or less of the square root of J, and particularly preferably 30% or less of the square root of J. Specific examples of the disposition of the auxiliary electrode satisfying such conditions include a method for making the shape of the transparent thin-film electrode not in contact with the auxiliary electrode short in the polarization direction of light transmitted through the transparent thin-film electrode and long perpendicular to the same direction, as shown in FIG. 1. Examples of such a shape can include a rectangle, a parallelogram, a rhombus, and so on. Also, in terms of decreasing electrical resistance, the maximum value Lmax is preferably smaller than 5 cm, further preferably smaller than 1 cm, still more preferably smaller than 1 mm, and particularly preferably smaller than 0.5 mm.

The material of the auxiliary electrode will be described. The auxiliary electrode may or may not be transparent, and materials having high electrical conductivity can be used. Generally, examples of the materials can include various carbons (carbon black, carbon nanotubes, graphite, and the like), and metals (copper, aluminum, chromium, gold, silver, platinum, iridium, osmium, tin, lead, titanium, molybdenum, tungsten, tantalum, niobium, vanadium, nickel, iron, manganese, cobalt, rhenium, and the like) and alloys thereof. For a method for manufacturing the auxiliary electrode, well-known methods can be used according to the selected material. Examples of the methods include methods, such as vapor deposition, sputtering, plating, application, and printing. When the auxiliary electrode is laminated on a portion in a plane of the transparent thin-film electrode, the auxiliary electrode can be laminated by these methods. The auxiliary electrode may be previously manufactured on a substrate on which the transparent thin-film electrode is to be formed, and may also be manufactured on a part of the transparent thin-film electrode after the transparent thin-film electrode is formed.

Next, the liquid crystal display of the present invention will be described. The liquid crystal display of the present invention can be obtained using the transparent thin-film electrode of the present invention for at least part of the transparent thin-film electrodes of a well-known liquid crystal display. As for the liquid crystal display mode used, display modes using at least one polarizing device among well-known liquid crystal display modes can be preferably used. Examples of such display modes include a twisted nematic (TN) type, a super-twisted nematic (STN) type, an optically compensated bend (OCB) type, a surface-stabilized ferroelectric liquid crystal (FLC) type, and an in-plane switching (IPS) type.

In apparatuses with these display modes, the transparent thin-film electrode or electrode composite of the present invention is used in at least one of electrodes for applying voltage to the liquid crystal. At this time, in the on-state of each display mode, that is to say, a state in which light transmitted through or reflected from the liquid crystal display is to be visually seen, a part of the polarized light which is transmitted through the transparent thin-film electrode is absorbed by the transparent thin-film electrode. It is particularly preferable that the polarization direction in the transparent thin-film electrode is substantially matched with the above polarized light so that this absorption is minimum. The above described “ . . . is substantially matched” means making the absorption minimized. Using this as a guideline, disposition can be determined. More specifically, a direction within 5 degrees from a direction in which the absorption is minimum is preferred, and a direction within 3 degrees is further preferred. Also, as for the constitution and disposition of actual members in each liquid crystal display mode, well-known ones can be used. At this time, in some cases, a liquid crystal orientation-inducing layer which is usually used can be omitted, and the transparent thin-film electrode can be used as the orientation-inducing layer.

The light-emitting device of the present invention will be described. The light-emitting device of the present invention is a light-emitting device having the transparent thin-film electrode of the present invention or the electrode composite of the present invention, and further a light-emitting layer, wherein the light emission from the light-emitting layer is polarized, and the polarization substantially matches the above polarization direction of the transparent thin-film electrode. As the system of the light-emitting device, a system in which some polarized light is radiated from a light-emitting site can be used among well-known light-emitting devices. In terms of a simple structure, a light-emitting diode, especially a system in which the light-emitting layer is of an organic molecule and polarized light is radiated (polarized OLED), is preferably used. The organic molecule used in the light-emitting layer can be appropriately selected from organic molecules known as being capable of forming a polarized OLED. Examples of the organic molecules can include conjugated polymers [polyfluorene, polyphenylene, polyphenylenevinylene, polythiophene, and the like] and derivatives thereof, and fluorescent dyes.

As the polarized OLED, well-known polarized OLEDs can be appropriately selected and used. In these systems, the transparent thin-film electrode of the present invention is used in at least one of electrodes. In other words, the polarized OLED has at least a cathode, an anode, and a light-emitting layer, and uses the transparent thin-film electrode of the present invention as the cathode or the anode or as a part thereof. In terms of the light emission performance of the light-emitting device, usually, the transparent thin-film electrode of the present invention is preferably used as the anode or a part thereof.

Here, the light-emitting layer comprises oriented organic molecules. The orientation can be performed by well-known methods. Specific examples of the methods can include mechanical methods (stretching, rolling, rubbing, and the like), methods for applying a magnetic field or an electric field, methods of using the orientation action of a surface, and so on. For example, a polarized OLED comprising oriented organic molecules can be manufactured according to methods described in JP 10-50314 T, JP 8-30654 A, JP 10-508979 T, and JP 11-503178 T. Usually, the polarization degree of light emitted from the light-emitting layer is preferably high. Specifically, the polarization degree is preferably 60% or more, more preferably 70% or more, still more preferably 80% or more, and particularly preferably 90% or more. Such a high degree of polarization can be achieved by increasing the orientation degree of the above organic molecules.

At this time, a part of polarized light radiated from the light-emitting layer is absorbed by the transparent thin-film electrode. The polarization direction of transmitted light in the transparent thin-film electrode is substantially matched with the above polarized light so that this absorption is minimum. The above “ . . . is substantially matched” means making the absorption minimized. Using this as a guideline, disposition can be determined. More specifically, a direction within 5 degrees from a direction in which the absorption is minimum is preferred, and a direction within 3 degrees is further preferred. Although the details depend on the type of organic molecules, in order to obtain such a match, it is usually preferable that the transparent thin-film electrode is not in direct contact with the light-emitting layer so that the orientation of the transparent thin-film electrode and the orientation of the light-emitting layer do not affect each other. One of the preferred orientation methods uses an orientation-inducing layer in contact with the light-emitting layer. The surface of the orientation-inducing layer in contact with the light-emitting layer is oriented using a method such as friction, and the light-emitting layer is oriented to have the desired polarization direction. It is preferable that such an orientation-inducing layer has a hole transport property.

### EXAMPLES

Examples are illustrated below to describe the present invention in more detail, but the present invention is not limited to these.

### Example 1

### Manufacturing 1 of Transparent Thin-Film Electrode

Chromium and then gold were previously vapor deposited on a portion 2 on a glass substrate 8 in FIG. 1, using a mask, to provide an auxiliary electrode 7. An ultrathin film of oriented polytetrafluoroethylene was formed on this substrate according to the method described in Nature, vol. 352, pp. 414 to 417 (1991). At this time, the polytetrafluoroethylene was not formed on the portion 2. Polyaniline was precipitated from concentrated sulfuric acid in which the polyaniline was dissolved. The precipitation was performed by allowing the solution to absorb moisture little by little from the atmosphere. The precipitated polyaniline film was oriented, and can be formed into a transparent thin-film electrode by removing the concentrated sulfuric acid solution. Good electrical contact can be obtained between the transparent thin-film electrode and the auxiliary electrode.

### Example 2

### Manufacturing of Liquid Crystal Display Device

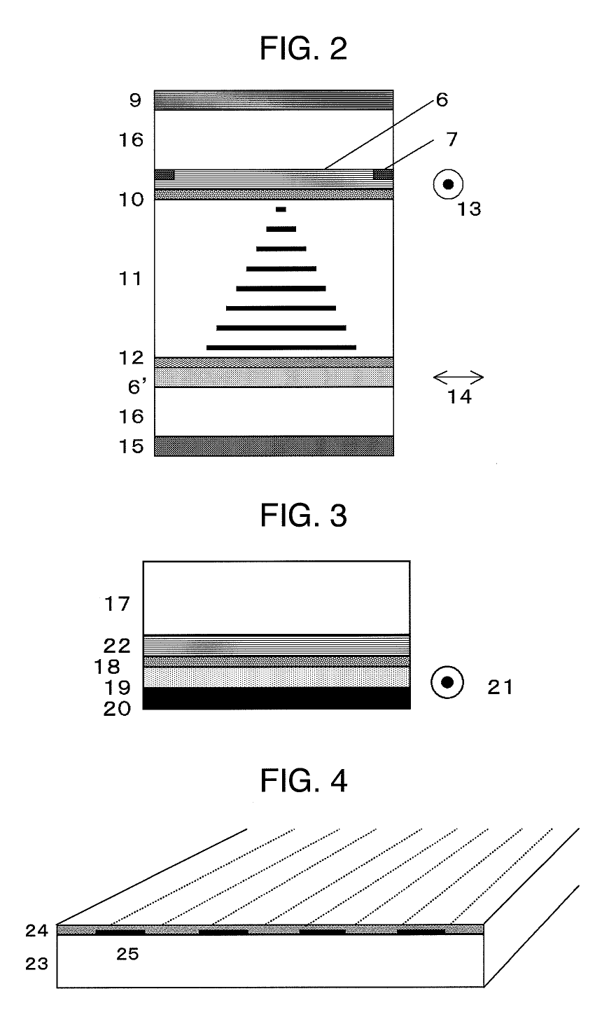

The transparent thin-film electrode obtainable in the above Example 1 can be used as the electrodes of a TN type liquid crystal display device in the structure of FIG. 2. At this time, the polarization direction of a polarizing film 9 constituting the TN type liquid crystal display device is matched with the polarization direction of a transparent thin-film electrode 6. Also, the polarization direction of the polarizing film 9 is matched with the polarization direction of a transparent thin-film electrode 6′. At this time, the orientation of the director of the TN type liquid crystal display device can be controlled by applying polyimide as liquid crystal orientation-inducing layers 10 and 12 on the transparent thin-film electrodes and performing friction. At this time, with no voltage applied between the transparent thin-film electrode 6 and the transparent thin-film electrode 6′, the polarization direction rotates 90 degrees in a TN-oriented liquid crystal 11, and therefore, polarized light entering from above and passed through 9 will not significantly be absorbed by 6 and further will not significantly be absorbed by 6′ and 15 either.

### Example 3

### Manufacturing of Light-Emitting Device

Oriented poly[3-(4-octylthiophene)] is transferred onto the transparent thin-film electrode obtainable in the above Example 1 according to the method described in Example 1 of JP 8-30654 A, and further, calcium and then aluminum is vapor deposited thereon as a cathode to manufacture a polarized OLED device. At this time, by matching the polarization direction of light emitted from the poly[3-(4-octylthiophene)] with the polarization direction of light transmitted through the transparent thin-film electrode, a brighter light emission will be obtained than that in a case where the polarization directions are not matched.

### Example 4

### Manufacturing 1 of Transparent Thin-Film Electrode

Chromium and then gold is previously vapor deposited on the portion 2 on the glass substrate 8 in FIG. 1, using a mask, to provide the auxiliary electrode 7. 20 layers of an LB film of carbon nanotubes are built up on this substrate by the vertical dipping method described in Technical Document 2. The obtainable transparent thin-film electrode has a D of about 1.8 at around 750 nm and can be used as a transparent thin-film electrode. (See Japanese Journal of Applied Physics, vol. 42, pp. 7629 to p. 7634 (2003).)

### Example 5

### Manufacturing 2 of Transparent Thin-Film Electrode

An aqueous solution of poly(3,4-ethylenedioxythiophene) doped with polystyrene sulfonic acid (BaytronP (registered trademark) A14083) was applied onto a glass substrate. A watercolor brush was immersed in the aqueous solution, and while the watercolor brush was moved back and forth in a fixed direction, the aqueous solution was applied. The brush was moved intermittently and continuously, while the aqueous solution was dried. When the viscosity was high, the aqueous solution was left and dried. It was confirmed that light transmitted through the film was polarized.

### Example 6

### Manufacturing 3 of Transparent Thin-Film Electrode

A wire grid polarizer for the visible light composed of aluminum or silver metal wires (width: 100 nm, pitch: 200 nm, wire thickness: 50 to 100 nm) was formed on a glass substrate. A polyamic acid solution for a liquid crystal was applied onto this wire grid polarizer and heated to form a polyimide film (film thickness: 0.1 micron). This polyimide film was rubbed with a cloth in parallel with the metal wires of the wire grid polarizer to manufacture a transparent thin-film electrode.

### Example 7

### Manufacturing of TN Type Liquid Crystal Display Device

Two of the transparent thin-film electrodes manufactured in Example 6 were bonded, with surfaces with the wire grid polarizer and the polyimide opposed to each other, to manufacture a liquid crystal cell. At this time, an epoxy resin mixed with 5 micron spacer beads was sandwiched in the peripheral part of the cell to provide a liquid crystal cell having a cell gap of about 5 microns. At this time, the polarization direction of one transparent thin-film electrode was perpendicular to the polarization direction of another transparent thin-film electrode. A TN liquid crystal composition was injected into the gap of the cell. When voltage was applied to this cell, a change in light transmitted through the cell was confirmed by the naked eye.

### Example 8

### Manufacturing 4 of Transparent Thin-Film Electrode

An aqueous solution of poly(3,4-ethylenedioxythiophene) doped with polystyrene sulfonic acid (BaytronP (registered trademark) A14083) was applied, with a film thickness of about 50 nm, onto the wire grid polarizer manufactured in Example 6.

1. A transparent thin-film electrode, wherein light transmitted through the transparent thin-film electrode is polarized.

2. The transparent thin-film electrode according to claim 1 comprising a conductive polymer.

3. The transparent thin-film electrode according to claim 1 comprising a carbon nanotube.

4. The transparent thin-film electrode according to claim 1 comprising an anisotropic metal fine particle.

5. The transparent thin-film electrode according to claim 1 comprising a wire grid structure of metal.

6. The transparent thin-film electrode according to claim 5 comprising a film comprising a conductive polymer or a carbon nanotube.

7. The transparent thin-film electrode according to claim 6, wherein the film comprising a conductive polymer or a carbon nanotube is disposed in a gap between adjacent metal wires forming the wire grid structure of metal.

8. The transparent thin-film electrode according to claim 6, wherein the film comprising a conductive polymer or a carbon nanotube is laminated on the wire grid structure of metal.

9. A composite transparent thin-film electrode comprising the transparent thin-film electrode according to claim 5 and a transparent thin-film electrode comprising a conductive polymer, wherein light transmitted through the transparent thin film electrode comprising the conductive polymer is polarized.

10. The composite transparent thin-film electrode according to claim 9, wherein the transparent thin-film electrode comprising a conductive polymer is laminated on a wire grid structure of metal.

11. The composite transparent thin-film electrode according to claim 9, wherein the transparent thin-film electrode comprising a conductive polymer is disposed in a gap between metal wires forming the wire grid structure of metal.

12. The composite transparent thin-film electrode according to claim 9, wherein the wire grid structure of metal has a polarization direction that substantially matches the polarization direction of the transparent thin-film electrode comprising a conductive polymer laminated.

13. The transparent thin-film electrode according to claim 1, wherein an orientation degree S in the transparent thin-film electrode is 0.1 or more.

14. The transparent thin-film electrode according to claim 1, wherein in a transmitted polarized absorption spectrum of light having a wavelength of 300 to 700 nm of the transparent thin-film electrode, a maximum absorbance value A1 of a polarized light in all directions in a film plane of a thin film is 0.1 or more.

15. An electrode composite comprising the transparent thin-film electrode according to claim 1 and at least one auxiliary electrode in contact with the transparent thin-film electrode.

16. The electrode composite according to claim 15, wherein a maximum value Lmax of the length L of a path from a point X on a surface of the transparent thin-film electrode not in contact with the auxiliary electrode to the auxiliary electrode, the path being perpendicular to a polarization direction of light transmitted through the transparent thin-film electrode and being shortest, is smaller than half a square root of a surface area J of the transparent thin-film electrode not in contact with the auxiliary electrode.

17. The electrode composite according to claim 15, wherein a maximum value Lmax of the length L of a path from a point X on the surface of the transparent thin-film electrode not in contact with the auxiliary electrode to the auxiliary electrode, the path being perpendicular to the polarization direction of light transmitted through the transparent thin-film electrode and being shortest, is smaller than 5 cm.

18. A liquid crystal display comprising the transparent thin-film electrode according to claim 1.

19. The liquid crystal display according to claim 18, further comprising at least one polarizing device, wherein the polarization direction of at least one polarizing device substantially matches the polarization direction of the transparent thin-film electrode.

20. A light-emitting device comprising the transparent thin-film electrode according to claim 1, and further a light-emitting layer, wherein light emitted from the light-emitting layer is polarized, and the polarization direction of the light-emitting layer substantially matches the polarization direction of the transparent thin-film electrode.

21. The light-emitting device according to claim 20, wherein the light-emitting device is a light-emitting diode.

22. The light-emitting device according to claim 21, wherein a light-emitting layer of the light-emitting diode comprises an oriented organic molecule.

23. The light-emitting device according to claim 22, wherein the organic molecule is a polymer.

24. The light-emitting device according to claim 20 comprising at least one orientation-inducing layer between the light-emitting layer and the transparent thin-film electrode.

25. A method for manufacturing the transparent thin-film electrode according to claim 1, the method comprising applying a force to a film comprising a solvent and a conductive polymer.
